(19) United States
(12) Patent Application Publication
(10) Pub. No.: US 2024/0194823 A1
(43) Pub. Date: Jun. 13, 2024

(54) TWO-DIMENSIONAL QUANTUM LIGHT EMITTING DEVICE

(71) Applicant: Naval Information Warfare Center Pacific, San Diego, CA (US)

(72) Inventors: Carlos M. Torres, JR., San Diego, CA (US); James R. Adleman, San Diego, CA (US); Sanja Zlatanovic, San Diego, CA (US)

(73) Assignee: THE UNITED STATES OF AMERICA AS REPRESENTED BY THE SECRETARY OF THE NAVY, San Diego, CA (US)

(21) Appl. No.: 18/063,751

(22) Filed: Dec. 9, 2022

(51) Int. Cl. H01L 33/06; H01L 33/42; H01L 33/56

(52) U.S. Cl. CPC H01L 33/06; H01L 33/42; H01L 33/56

(57) ABSTRACT

A two-dimensional quantum light emitting device includes a substrate, two or more monolayers, one or more positive electrodes, and one or more negative electrodes. The substrate grows two or more monolayers on a surface of the substrate. The two or more monolayers have a tunable bandgap ranging from about 477 nm to about 620 nm and have a tunable twist angle. The one or more positive electrodes and the one or more negative electrodes provide a current to an active region of the two or more monolayers and are interdigitated electrodes, non-interdigitated electrodes, piezoelectric electrodes, or a combination thereof that tune the twist angle of the two or more monolayers in-situ.

### BACKGROUND

Quantum light sources have broad applicability to multiple existing and emerging technologies including computing, microscopy, networking and data communication. Scalable low cost solid state emitters that can address all areas of the visible and infrared bands are desired. However, production of bright quantum light sources occupy the blue green portion of the visible spectrum is challenging due to the high photon energies needed to perform either direct emission or frequency conversion to produce quantum light emission. 2d semiconductor materials are attractive due to their simple fabrication and low size weight and power requirements as well as their tunable band gap energies. However, existing monolayer 2-D semiconductors have band gap energies that limit emission to wavelengths longer than 600 nm, making the blue and green portions of the band inaccessible.

### DESCRIPTION OF THE DRAWINGS

Features and advantages of examples of the present disclosure will be apparent by reference to the following detailed description and drawings, in which like reference numerals correspond to similar, but in some instances, not identical, components. Reference numerals or features having a previously described function may or may not be described in connection with other drawings in which they appear.

FIG. 1 is a cross-sectional view of an example of the two-dimensional quantum light emitting device disclosed herein;

FIG. 2 is a top view of an example of the two-dimensional quantum light emitting device disclosed herein with a magnified active region, which includes a Moire periodic potential manifested by the relative twist angle imparted by the 2D material of the top monolayer with respect to the 2D material of the bottom monolayer underneath the top monolayer;

FIG. 3 is a cross-sectional view of an example of the two-dimensional quantum light emitting device with encapsulation layers above and below the top and bottom monolayers; and

FIG. 4 is a cross-sectional view of an example of the two-dimensional quantum light emitting device with an encapsulation layer (e.g. representative of an ionic liquid or ion-gel) above the two or more monolayers and a transparent top-gate electrode residing above the active region of the two or more monolayers.

### DETAILED DESCRIPTION

A two-dimensional quantum light emitting device is described herein that includes a substrate, two or more monolayers, and one or more positive electrodes and one or more negative electrodes. The substrate can grow two or more monolayers on a surface of the substrate. The two or more monolayers have a tunable bandgap ranging from about 477 nm to about 620 nm and have a tunable twist angle. The one or more positive electrodes and the one or more negative electrodes provide a current to an active region of the two or more monolayers and are interdigitated electrodes, non-interdigitated electrodes, piezoelectric electrodes, or a combination thereof that tune the twist angle of the two or more monolayers in-situ.

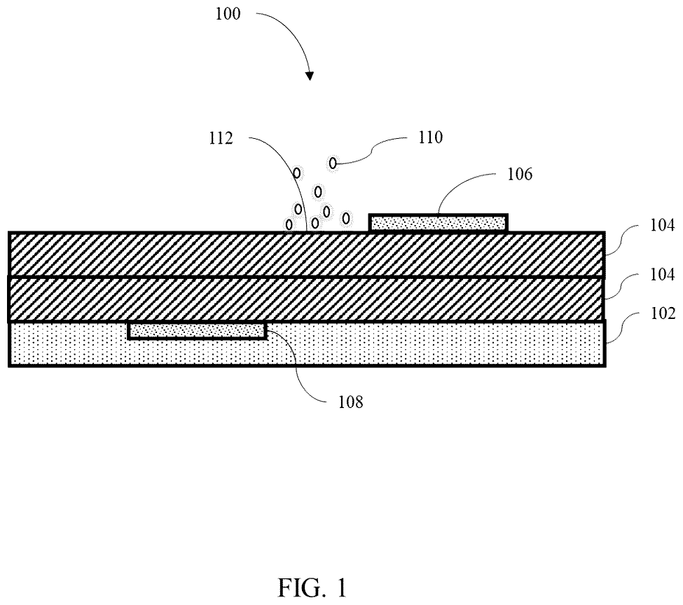

Referring now to FIG. 1, a cross-sectional view of an example of the two-dimensional quantum light emitting device 100 is shown. The hatching pattern in FIG. 1 is for illustrative purposes only to aid in viewing and should not be construed as being limiting or directed to a particular material or materials. The quantum light emitting device 100 includes a substrate 102 that grows two or more monolayers on a surface of the substrate. The substrate 102, the one or more positive electrodes 106, and one or more negative electrodes 108 are used to provide opposite polarity voltages to the two or more monolayers 104 to inject electrons or holes into the two or more monolayers 104. The electrons pair up into excitons in the potential wells of the Moire periodic potential at the interface of the two or more monolayers 104. These excitons radiatively recombine in the potential wells and emit a single quantum photon. In an example, the substrate 102 is composed of one or more layers of SiO₂, Si, SiO₂/Si, sapphire, hexagonal boron nitride, Si₃N₄, or a combination of Si, SiO₂, and hexagonal boron nitride. In an example, when a combination of Si, SiO₂, and hexagonal boron nitride is used, the bottom layer may be Si, the inner layer may be SiO₂, and the outer layer may be one or more layers of the hexagonal boron nitride that acts as a buffer layer to “shield” away the Coulomb fields arising from the charged impurities in the inner SiO₂ layer. In some examples, the substrate has a thickness ranging from about 90 nm to about 1 micron.

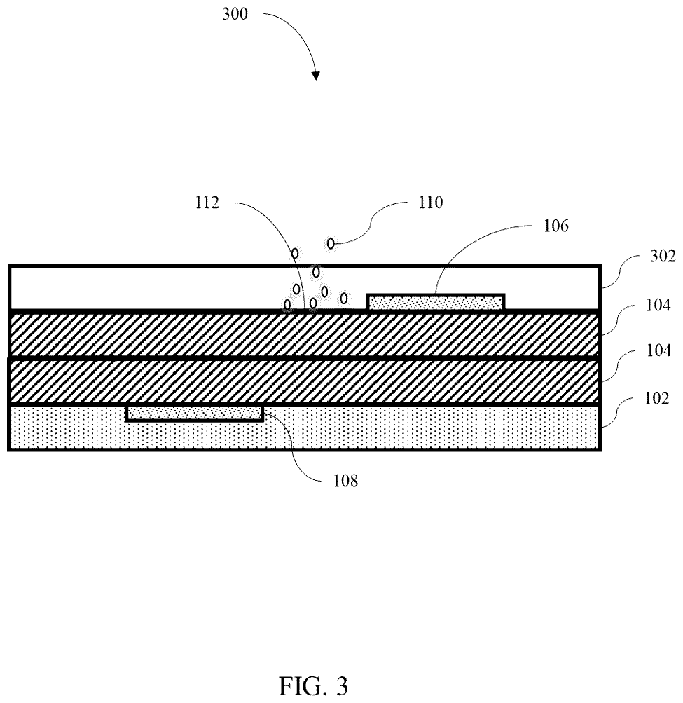

Referring back to FIG. 1, the two-dimensional quantum light emitting device 100 includes two or more monolayers 104. The two or more monolayers 104 have a tunable bandgap ranging from about 477 nm to about 620 nm. The ability to tune the energy bandstructure of the two or more monolayers 104 is possible using twistronics, the Stark Effect, or a combination of both. A tunable twist angle is used when stacking the two or more monolayers 104 together that causes quantum light to be emitted from the device at a specific bandgap depending upon the application of the device, the material of the two or more monolayers 104, and the desired bandgap. In an example, the tunable twist angle may range from about 1° to about 60° between each monolayer of the two or more monolayers 104. The tunable twist angle is tunable via surface electrodes 106, 108 via twistronics. FIG. 1 and FIG. 3 show examples of a two-dimensional quantum light emitting device 100 with surface electrodes 106, 108. The surface electrodes 106, 108 exhibit Schottky Barriers.

In another example, the Stark effect is used to tune the direct bandgap. In this example, a vertical electric field is provided by biasing a top-gate electrode through an ion-gel top-gate dielectric to in-situ decrease or increase the bandgaps of the monolayers 104 in the two-dimensional quantum light emitting device 100. The top-gate electrode can be either positively or negatively biased with respect to the surface electrodes 106, 108. The top-gate electrode is positively or negatively bias with one or both of the surface electrodes 106, 108 being grounded. This creates a top-gate electric vertical field across the top-gate dielectric, which will induce an electric dipole layer (EDL) to exist in the vicinity of the surface of the top most monolayer 104 in the device 100. The vertical electric field will be confined to this EDL sub-nanometer thick layer and cause a Stark shift of the bandgap of the underlying two monolayers 104. The top-gate electrode is discussed in detail herein.

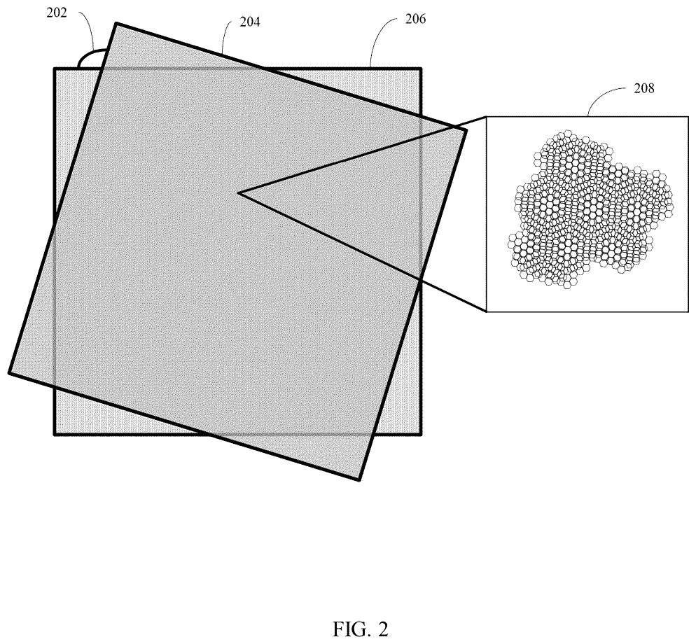

An example of the twist angle 202 in the two-dimensional quantum light emitting device 100 is shown in FIG. 2. The hatching pattern in FIG. 2 is for illustrative purposes only to aid in viewing and should not be construed as being limiting or directed to a particular material or materials. The twist angle 202 is created by stacking a first monolayer 204 on top of a second monolayer 206. In other examples, more than two monolayers are used and there are multiple twist angles 202 between each monolayer. The twist angle 202 creates a Moire periodic potential, which is shown in a magnified view 208 of the first and second monolayers 204, 206 stacked together. Electrode 106 is attached to one monolayer (i.e., the first monolayer 204 in FIG. 2), whereas electrode 108 is attached to the other monolayer (e.g. the second monolayer 206 in FIG. 2). Furthermore, it is implied that the positive electrode or positive electrodes are contacting the positively-doped monolayer (e.g. p-type monolayer), whereas the negative electrode or negative electrodes are contacting the negatively-doped monolayer (e.g. n-type monolayer). This facilitates the electrical injection of either electrons or holes into the n-type and p-type monolayers, respectively, for their subsequent combination into excitons once injected into the active region of the two-dimensional quantum light emitting device 100. In other examples, the electrodes 106 and 108 may be encapsulated between the two monolayers 104 if the monolayers 104 are graphene monolayers 104 that remain external to the active twistronic Moire periodic potential region of the two-dimensional quantum light emitting device 100. The electrodes 106, 108 are discussed in detail below.

The two or more monolayers 104 may be composed of GaS₁₋ₓSeₓ alloy where x ranges from about 0 to about 1. For example, the two or more monolayers 104 may be GaS, GaS_{0.35}Se_{0.65}, GaS_{0.7}Se_{0.3}, GaS_{0.2}Se_{0.8}, GaS_{0.5}Se_{0.5}, or a combination thereof. In another example, the two or more monolayers 104 may be composed of one or more 2D semiconductors. Some examples of the one or more 2D semiconductors include MoS₂, MoSe₂, WS₂. WSe₂, graphene, black phosphorus, and combinations thereof.

Referring back to FIG. 1, the two-dimensional quantum light emitting device 100 includes one or more positive electrodes 106 and one or more negative electrodes 108 that are interdigitated electrodes, non-interdigitated electrodes, piezoelectric electrodes, or a combination thereof that are capable of tuning the twist angle of the two or more monolayers 104 in-situ. In the example in FIG. 1, there is one positive electrode 106 and one negative electrode 108 that provide a current to an active region 112 of the two or more monolayers 104. The positive electrode 106 will inject holes into the positively doped monolayer material. The negative electrode 108 will inject electrons into the negatively doped monolayer material. The electrons and holes combine into excitons in the active region 112 and eventually emit single photons 110 (quantum light). The electrodes 106, 108 make contact with the two monolayers outside of the active region 112 for electrical injection of holes and electrons, which combine into excitons in the active region 112 (not depicted in FIG. 1). The excitons are trapped in the Moire periodic potentials at the interface between the two monolayers 104 and are subsequently recombined and radiated from the surface of the outermost monolayer 104 as single photons 110.

In an example, the electrodes 106, 108 may be composed of any material that is capable of providing a current to the active region 112. Some examples that the electrodes 106, 108 may be composed of include a metal (e.g., titanium adhesion layer with gold on top), transparent conducting oxide (e.g., indium tin oxide), graphene, or a combination thereof. Similarly, the electrodes 106, 108 may be any type of electrode capable of providing current to the active regions 112 of the two or more monolayers 104. Some examples of the electrodes 106, 108 include transparent, conducting or transparent and conducting electrodes 106, 108 with various shapes. For example, the electrodes 106, 108 may be circular, hemispherical, linear, or any other shape that forms an electrode capable of providing a current to the active region of the two or more monolayers 104. The electrodes 106, 108 include a current that is provided by a voltage source that induces a current through the two-dimensional quantum light emitting device 100. In an example, the current may range from about 1 pA to about 100 mA.

The location of the one or more positive and negative electrodes 106, 108 within the two-dimensional quantum light emitting device 100 may vary. In one example, the one or more positive electrodes 106 and the one or more negative electrodes 108 are deposited vertically on top of the two or more monolayers 104 (i.e., a surface contact electrode) as shown in FIG. 1. In another example, the electrodes 106, 108 can be encapsulated within the substrate 102 where the substrate 102 includes one or more monolayers as previously disclosed herein. In yet another example, the electrodes 106, 108 may be deposited on an edge of the two or more monolayers 104 (not shown in FIG. 1). In this example, a special deposition is made that allows only the edge atoms of the two or more monolayers 104 to make physical contact with the electrodes 106. 108. This results in an Ohmic conducting contact rather than more resistive Schottky Barrier contact when depositing the electrodes 106, 108 vertically on top of the two or more monolayers 104.

Another example of the location of the one or more electrodes 106, 108 is shown in FIG. 3. The hatching pattern in FIG. 3 is for illustrative purposes only to aid in viewing and should not be construed as being limiting or directed to a particular material or materials. FIG. 3 shows a two-dimensional quantum light emitting device 300 with an encapsulation layer 302. The substrate 102 and two or more monolayers 104 are the same substrate 102 and two or more monolayers 104 as previously disclosed herein. There may be one or more encapsulation layers 302, however the example shown in FIG. 3 includes one encapsulation layer 302. The encapsulation layer 302 encapsulates the electrodes 106, 108 to route different voltages to different spatial regions of the circuit and precludes any shorting of the circuit. In an example, the encapsulation layer 302 is one or more layers of hexagonal boron nitride. In another example, the encapsulation layer 302 is one or more layers of high dielectric constant materials, such as HfO₂ or Al₂O₃.

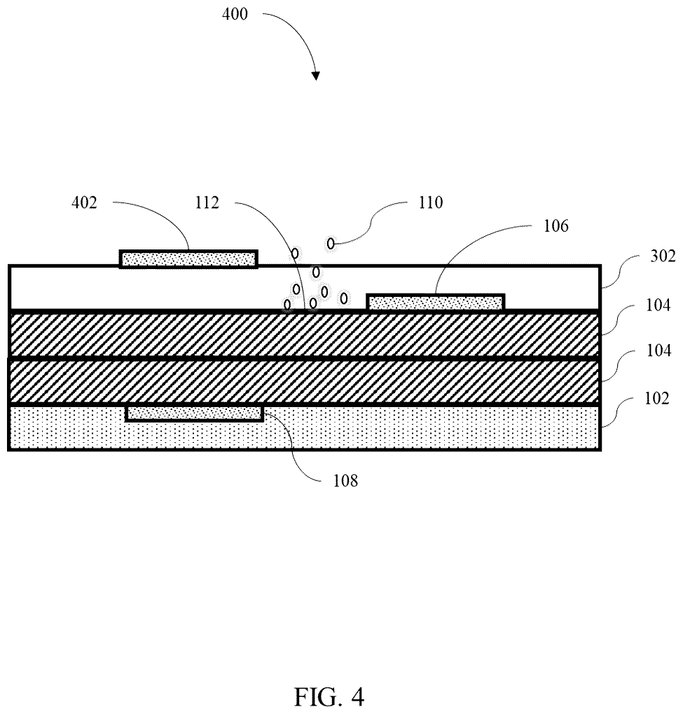

Another example of the two-dimensional quantum light emitting device 400 is shown in FIG. 4. The two-dimensional quantum light emitting device 400 further includes a top-gate electrode 402 attached to a top-gate dielectric encapsulation layer 302. The hatching pattern in FIG. 4 is for illustrative purposes only to aid in viewing and should not be construed as being limiting or directed to a particular material or materials. The top-gate electrode 402 is composed of a metal, transparent conducting oxide, graphene, or a combination thereof and generates an electric field near the active region of the two or more monolayers to induce an in-situ bandgap modulation via the Stark Effect. Some example of the top-gate dielectric include HfO₂, Al₂O₃, ion-gel, ionic liquid, or one or more hexagonal boron nitrde layers. When a top-gate electrode is used, the top-gate voltage produced by the top-gate electrode induces an electric field near the vicinity of the two monolayers 104 that are capable of modulating the bandgap (i.e., the optical bandgap) of the active region 112 in the two or more monolayers 104 such that the wavelength of the emitted quantum light can be tuned via the Stark Effect.

In the example in FIG. 4, the encapsulation layer 302 is one or more layers of ionic liquids or ion-gels, which exhibit an electric dipole layer near the two or more monolayers 104 upon the application of a top-gate voltage via the top-gate electrode 402. The ion-gel or ionic liquid layers function as both an encapsulation layer 302 and top-gate dielectric that exhibits an electric dipole layer with electric fields concentrated or confined near the two or more monolayers 104 when applying a vertical electric field across the encapsulation layer 302. The top-gate electrode 402 applies the vertical electric field to allow the quantum light to pass through the encapsulation layer 302. The ion-gel or ionic liquid layers (i.e., the encapsulation layer 302 in FIG. 4) are capable of increasing or decreasing the tunable bandgap of the two or more monolayers via the Stark Effect by voltage-biasing across a top-gate electrode 402 and the one or more positive electrodes 106 and one or more negative electrodes 108. The voltage biasing induces a strong electric field inside the sub-nanometer sized electric dipole layer of the ion-gel or ionic liquid in the vicinity of the surface of the two or more monolayers.

In some examples the two-dimensional quantum light emitting device 100, 300, 400 may be attached to an integrated circuit or the substrate 102 as part of the integrated circuit. When the integrated circuit is attached to the two-dimensional quantum light emitting device 100, 300, 400, the integrated circuit is attached to the substrate 102 surface on the opposite surface of the two or more monolayers 104. In other examples, the integrated circuit forms the substrate 102 where the two or more monolayers 104, the electrodes 106, 108, and any encapsulation layers 302 (if used) are deposited directly onto the integrated circuit.

A two-dimensional quantum light emitting system is also disclosed herein. The two-dimensional quantum light emitting system includes a substrate, two or more monolayers, and one or more positive electrodes and one or more negative electrodes. The substrate, two or more monolayers, and one or more positive electrodes and one or more negative electrodes are the same substrate, two or more monolayers, and one or more positive electrodes and one or more negative electrodes as previously disclosed herein.

As used herein, the term “about” is used to provide flexibility to a numerical range endpoint by providing that a given value may be “a little above” or “a little below” the endpoint. The degree of flexibility of this term can be dictated by the particular variable and would be within the knowledge of those skilled in the art to determine based on experience and the associated description herein.

As used herein, a plurality of items, structural elements, compositional elements, and/or materials may be presented in a common list for convenience. However, these lists should be construed as though each member of the list is individually identified as a separate and unique member. Thus, no individual member of a list should be construed as a de facto equivalent of any other member of the same list merely based on their presentation in a common group without indications to the contrary.

Unless otherwise stated, any feature described herein can be combined with any aspect or any other feature described herein.

Reference throughout the specification to “one example”, “another example”, “an example”, means that a particular element (e.g., feature, structure, and/or characteristic) described in connection with the example is included in at least one example described herein, and may or may not be present in other examples. In addition, the described elements for any example may be combined in any suitable manner in the various examples unless the context clearly dictates otherwise.

The ranges provided herein include the stated range and any value or sub-range within the stated range. For example, a range from about 477 nm to about 620 nm should be interpreted to include not only the explicitly recited limits of from about 477 nm to about 620 nm, but also to include individual values, such as 537 nm, 577 nm, 610 nm, etc., and sub-ranges, such as from about 500 nm to about 600 nm, etc.

In describing and claiming the examples disclosed herein, the singular forms “a”, “an”, and “the” include plural referents unless the context clearly dictates otherwise.

What is claimed is:

1. A two-dimensional quantum light emitting device, comprising:
a substrate, wherein the substrate grows two or more monolayers on a surface of the substrate;
two or more monolayers, wherein the two or more monolayers have a tunable bandgap ranging from about 477 nm to about 620 nm and have a tunable twist angle
one or more positive electrodes and one or more negative electrodes, wherein the one or more positive electrodes and the one or more negative electrodes provide a current to an active region of the two or more monolayers and are interdigitated electrodes, non-interdigitated electrodes, piezoelectric electrodes, or a combination thereof that tune the twist angle of the two or more monolayers in-situ.

2. The two-dimensional quantum light emitting device of claim 1, wherein the substrate is composed of one or more layers of SiO₂, Si, SiO₂/Si, sapphire, hexagonal boron nitride, Si₃N₄, or a combination of Si, SiO₂, and hexagonal boron nitride.

3. The two-dimensional quantum light emitting device of claim 1, wherein the two or more monolayers are composed of GaS₁₋ₓSeₓ alloy where x ranges from about 0 to about 1, one or more 2D semiconductors, or a combination thereof.

4. The two-dimensional quantum light emitting device of claim 3, wherein the 2D semiconductors are selected from the group consisting of MoS₂, MoSe₂, WS₂, WSe₂, graphene, black phosphorus, and combinations thereof.

5. The two-dimensional quantum light emitting device of claim 1, further including a voltage source, wherein the voltage source induces a current through the two-dimensional quantum light emitting device.

6. The two-dimensional quantum light emitting device of claim 1, wherein the one or more positive electrodes and one or more negative electrodes are composed of a metal, transparent conducting oxide, graphene, or a combination thereof.

7. The two-dimensional quantum light emitting device of claim 1, wherein the twist angle ranges from about 1° to about 60° between each monolayer of the two or more monolayers.

8. The two-dimensional quantum light emitting device of claim 1, wherein one or more positive electrodes and one or more negative electrodes are surface contact electrodes, encapsulated within the substrate, encapsulated within the two or more monolayers, or deposited on an edge of a surface of the two or more monolayers.

9. The two-dimensional quantum light emitting device of claim 1, wherein the two-dimensional quantum light emitting device is attached to an integrated circuit or the substrate is part of the integrated circuit.

10. The two-dimensional quantum light emitting device of claim 1, further including one or more encapsulation layers, wherein the encapsulation layers are deposited onto the two or more monolayers.

11. The two-dimensional quantum light emitting device of claim 10, wherein the encapsulation layers are one or more layers of ionic liquids or ion-gels that are capable of increasing or decreasing the tunable bandgap of the two or more monolayers in the active region via a Stark Effect by biasing an electric field across a top-gate electrode, the one or more positive electrodes, and one or more negative electrodes.

12. The two-dimensional quantum light emitting device of claim 1, further including a top gate electrode, wherein the top gate electrode is composed of a metal, transparent conducting oxide, graphene, or a combination thereof and generates an electric field near the active region of the two or more monolayers to induce an in-situ bandgap modulation via the Stark Effect.

13. A two-dimensional quantum light emitting system, comprising:
a substrate, wherein the substrate grows two or more monolayers on a surface of the substrate;
two or more monolayers, wherein the two or more monolayers have a tunable bandgap ranging from about 477 nm to about 620 nm and have a tunable twist angle;
one or more positive electrodes and one or more negative electrodes, wherein the one or more positive electrodes and the one or more negative electrodes provide a current to an active region of the two or more monolayers and are interdigitated electrodes, non-interdigitated electrodes, piezoelectric electrodes, or a combination thereof that tune the twist angle of the two or more monolayers in-situ.

14. The two-dimensional quantum light emitting system of claim 13, wherein the substrate is composed of one or more layers of SiO₂, Si, SiO₂/Si, sapphire, hexagonal boron nitride, Si₃N₄, or a combination of Si, SiO₂, and hexagonal boron nitride.

15. The two-dimensional quantum light emitting system of claim 13, wherein the two or more monolayers are composed of GaS₁₋ₓSeₓ alloy where x ranges from about 0 to about 1, one or more 2D semiconductors, or a combination thereof.

16. The two-dimensional quantum light emitting system of claim 13, wherein the one or more positive electrodes and one or more negative electrodes are composed of a metal, graphene, transparent conducting oxide, or a combination thereof.

17. The two-dimensional quantum light emitting system of claim 13, wherein the twist angle ranges from about 1° to about 60°.

18. The two-dimensional quantum light emitting system of claim 13, wherein the one or more positive electrodes and one or more negative electrodes are surface contact electrodes, encapsulated within the substrate, encapsulated within the two or more monolayers, or deposited on an edge of a surface of the two or more monolayers.

19. The two-dimensional quantum light emitting system of claim 13, further including a top gate electrode, wherein the top gate electrode is composed of a metal, transparent conducting oxide, graphene, or a combination thereof and generates an electric field near the active region of the two or more monolayers to induce an in-situ bandgap modulation via the Stark Effect.

20. The two-dimensional quantum light emitting system of claim 13, further including one or more encapsulation layers, wherein the encapsulation layers are deposited onto the two or more monolayers and are one or more layers of ionic liquids or ion-gels that are capable of increasing or decreasing the tunable bandgap of the two or more monolayers in the active region via a Stark Effect by biasing an electric field across a top-gate electrode, the one or more positive electrodes, and one or more negative electrodes.
